(19) United States
(12) Patent Application Publication
(10) Pub. No.: US 2018/0145083 A1
(43) Pub. Date: May 24, 2018

(54) CONTROLLED MODIFICATION OF ANTIFUSE PROGRAMMING VOLTAGE

(71) Applicant: Intel Corporation, Santa Clara, CA (US)

(72) Inventors: Xiaoghong TONG, Hillsboro, OR (US); Walid M. HAFEZ, Portland, OR (US); Zhiyong MA, Hillsboro, OR (US); Peng BAI, Hillsboro, OR (US); Chia-Hong JAN, Portland, OR (US); Zhanping CHEN, Portland, OR (US)

(21) Appl. No.: 15/575,792

(22) PCT Filed: Jun. 25, 2015
(86) PCT No.: PCT/US2015/037762

§ 371 Date: Nov. 20, 2017

(51) Int. Cl. H01L 27/112; G11C 17/16; H01L 23/525

(52) U.S. Cl. CPC H01L 27/11206; H01L 23/5252; G11C 17/16

(57) ABSTRACT

The controlled modification of an antifuse programming voltage is described. In one example, an antifuse circuit is formed on a substrate, including a gate area of the antifuse circuit. A molecule is implanted into the gate area to damage the structure of the gate area. Electrodes are formed over the gate areas to connect the antifuse circuit to other components.

### FIELD

The present description relates to antifuse circuits in semiconductor electronics and in particular to modifying the programming voltage of such a circuit.

### BACKGROUND

Metal fuse and antifuse elements are used for a wide range of different electronic devices. One common use is in non-volatile memory arrays. They are also used in processors to set parameter and register values or to set codes, serial numbers, encryption keys and other values that are not to be changed later. Fuse and antifuse elements are used in bipolar, FinFET, and CMOS (Complementary Metal Oxide Semiconductor) device technologies, among others.

As an example, programmable memory devices such as PROM (programmable read-only memory) and OTPROM (one-time programmable read-only memory) are typically programmed by either destroying links (via a fuse) or creating links (via an antifuse) within the memory circuit. In PROMs, for instance, each memory location or bitcell contains a fuse and/or an antifuse, and is programmed by triggering one of the two. The programming is usually done after manufacturing of the memory device, and with a particular end-use or application in mind. Once conventional bitcell programming is performed, it is generally irreversible.

Fuse links are commonly implemented with resistive fuse elements that can be open-circuited or “blown” by applying an unusually high-current on an appropriate line. Antifuse links, on the other hand, are typically implemented with a thin barrier layer of non-conducting material (such as silicon dioxide) between two conducting layers or terminals. When a sufficiently high voltage is applied across the terminals, the silicon dioxide is damaged eliminating the barrier so that there is a low resistance conductive path between the two terminals.

### BRIEF DESCRIPTION OF THE DRAWINGS

Embodiments are illustrated by way of example, and not by way of limitation, in the figures of the accompanying drawings in which like reference numerals refer to similar elements.

FIG. 1 is a circuit diagram of a portion of an antifuse bit cell memory array according to an embodiment.

FIGS. 2-12 are side cross-sectional view diagrams of a first sequence of fabrication stages for an antifuse device with a modified programming voltage according to an embodiment.

FIGS. 13-19 are side cross-sectional view diagrams of a second sequence of fabrication stages for an antifuse device with a modified programming voltage according to an embodiment.

FIG. 20 is a block diagram of a computing device incorporating a tested semiconductor die according to an embodiment.

### DETAILED DESCRIPTION

One use of anti-fuse technology is for one-time-programmable (OTP) memory arrays. These are typically constructed using polysilicon fuses, metal fuses, and oxide anitfuses. Polysilicon and metal fuse arrays traditionally have larger footprints than oxide antifuse arrays, in part due to the large current required to fuse the element. Oxide antifuses rely on an oxide layer between conductive electrodes to form the fusing element. The oxide layer could be gate oxide in a MOS device. The electrodes could be the gate and the silicon substrate. For the MOS antifuse element, a diffusion layer is used for the source and drain regions, and a gate is formed on top of the diffusion layer and insulated from the diffusion layer by an oxide layer. The programming voltage breaks down the oxide insulation layer.

A driver circuit is used to program an antifuse circuit. The higher the programming voltage, the larger and more expensive the driver circuit may be. If there are many antifuse circuits, then the ease of programming is an important factor for the antifuse circuit design. A lower antifuse programming voltage has a simpler circuit design, lower manufacturing cost, reduced collateral damage in use, and may also allow in-field programming. The ability to lower the oxide breakdown voltage of antifuse elements relative to the devices used in the rest of the circuit also helps simplify the design, lower the cost and increase the reliability of the overall circuit.

The programming voltage of an antifuse circuit depends on the gate oxide breakdown voltage. Different circuit technologies may require different voltages. Metal gate and high K metal oxide antifuse circuits typically require a higher voltage than polysilicon gates that use silicon dioxide as the gate dielectric for the same technology node generation.

As described herein, an implant process may be used to lower the gate dielectric breakdown voltage for a high K metal gate oxide, a regular gate oxide, or any other gate dielectric material. The implant may be applied with other areas of a device masked so that the implant only affects the high K metal gate oxide of a fuse element. This provides a lower voltage antifuse programming circuit with less cost and complexity.

By implanting heavy molecules through and into a high K metal gate oxide the breakdown voltage on an antifuse circuit is lowered. A masking layer may be used to protect other elements of the circuit. In this way, the antifuse elements have a lower breakdown voltage and the protected surrounding normal high K metal gates are not affected. This implanting is simpler and easier to control than changing the basic structure of the high K gate oxide or antifuse circuit.

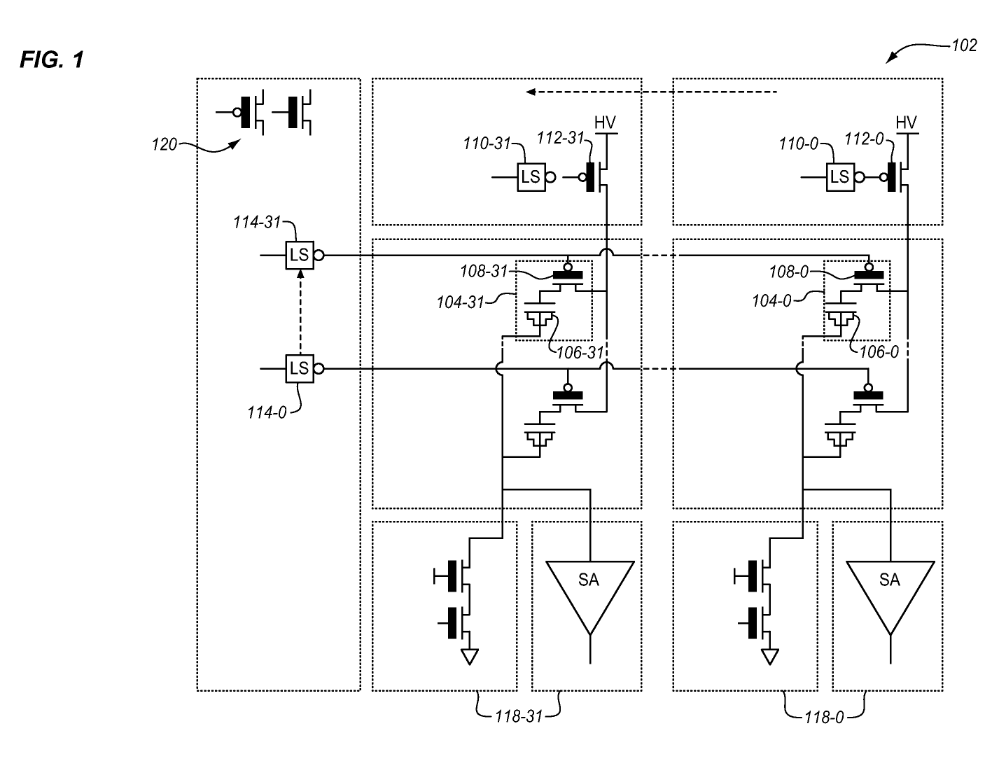

FIG. 1 is a simplified diagram of a portion of an antifuse circuit array 102. The array includes many devices, most of which are fabricated using conventional designs. Some of the devices relating to the antifuse functions are manufactured with gates with thick gate oxide 120 (Thick Gates) to handle high voltage. These devices are shown differently in the drawing figure as indicated by a special thick gate devices graphic legend 120. In the illustrated example, the array has thirty-two antifuse cells 104-31 to 104-0, although only two cells are shown. There may be more or fewer cells than shown. The array may be part of a die specifically for antifuse cells or the array may be integrated into another system. Each cell 104 has an antifuse switch 106-31 . . . 106-0 and a high voltage fuse signal driver 108-31 . . . 108-0. Upon receiving an appropriate fuse signal, the driver 108 drives a high voltage through the gate of the antifuse switch 106 to program the antifuse cell. By programming some antifuse cells and not others a sequence of zeros and ones may be programmed across an array to store identification numbers, encryption keys, operational parameters and other values.

The cells of the array are accessed for programming using a column line selector 110-31 . . . 110-0 for each column of the array and a row line selector 114-31 . . . 114-0 for each row of the array. Each column selector 110 is coupled to a high voltage line driver 112-31 . . . 112-0 to send a high voltage on the selected line to an appropriate cell 104. Combining the column selection 110 and the row selection 114, a single cell 104 of the array may be selected for programming. As shown, the column selectors are coupled to the source of each cell's fuse voltage driver and the row selectors are coupled to the gate of each cell's fuse driver. When the high voltage is applied to a source and the gate is opened, then the high voltage is driven through the gate oxide of the antifuse switch 106 to program the circuit.

While the driver circuits operate at a high voltage, the rest of the system operates on a Vcc or Vss voltage 118-31 . . . 118-0. This voltage is applied to the gates and sources of the antifuse cells 106 to read the value that was programmed into the cell. The high voltage circuit is used for all of the antifuse programming and this uses devices at each cell and also on the column select for each column. The higher the programming voltage, the higher the requirement for the circuit to be able to handle the high voltage needed for the programming. Higher voltages require higher cost and higher complexity for the circuit design. Lowering the antifuse programming voltage reduces these costs.

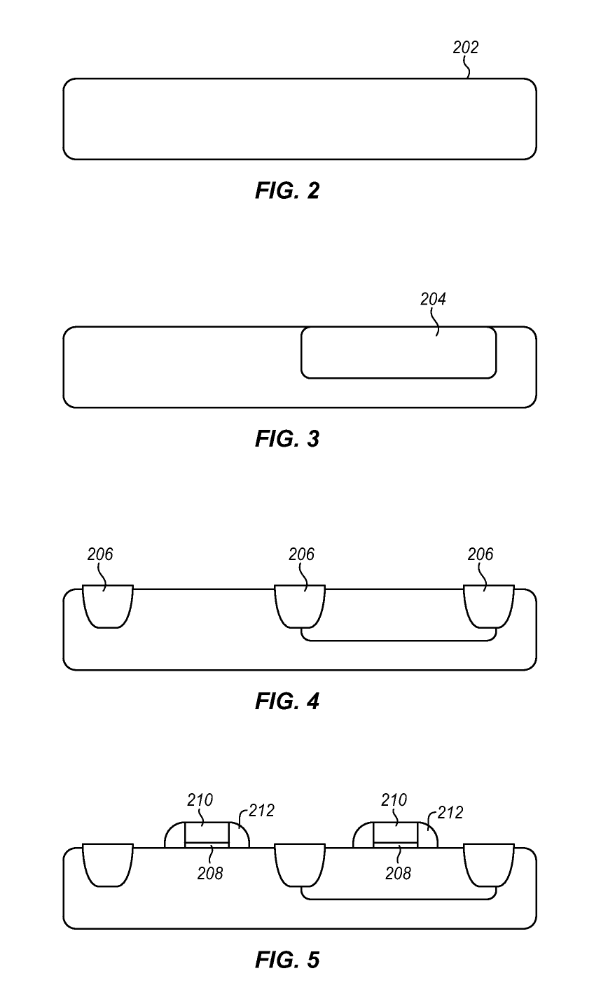

FIGS. 2-12 are cross-sectional side view diagrams of a sequence of processing stages in a fabrication sequence for production of an antifuse circuit with a lowered programming voltage. FIG. 2 is a first cross-sectional side view diagram of a process stage in a first fabrication sequence for production of an antifuse circuit with a lower programming voltage. Initially a substrate 202 is used. The substrate may be a silicon wafer upon which many dies are formed or the substrate may have a different size and be formed of a different material. In the illustrated example, two transistors are formed in the substrate as an example to show fabrication stages. Typically an array of transistors will be formed in the same substrate together with read, write, and programming circuits. Additional logic and memory circuits may also be formed in the substrate.

FIG. 3 shows the substrate 202 of FIG. 2 after an n-well 204 has been formed on one side. An n-type MOS transistor or NMOS transistor will be formed on this side, the right side, while a PMOS transistor will be formed on the left side. The material of the substrate forms a p-well for the left side transistor. Note that the process described here is different from normal MOS device formation. Normally a PMOS transistor would be formed in the n-well and a NMOS transistor would be formed in the p-well for a regular CMOS circuit and this process may also be used for antifuse element formation.

FIG. 4 shows the addition of shallow trench isolation (STI) areas 206 on either side of the n-well. A third STI area 206 is formed on the left side of the n-well to define boundaries for the p-well. These areas may be added using photolithography, for example, by masking some areas, removing, depositing or implanting materials in the exposed areas and then removing the photoresist mask.

FIG. 5 shows the substrate 202 with regular gate oxide (e.g., SiO₂ and variations) 208 deposited over the substrate and then a layer of polysilicon 210 deposited over the gate oxide. The Polysilicon layer is patterned using, for example, a dry etch so that the layers remain only where high k metal gate oxides and metal gates later will be. A nitride spacer 212 is then formed around each polysilicon gate with regular oxide next to the locations where the S/D (Source/Drain) implants will be.

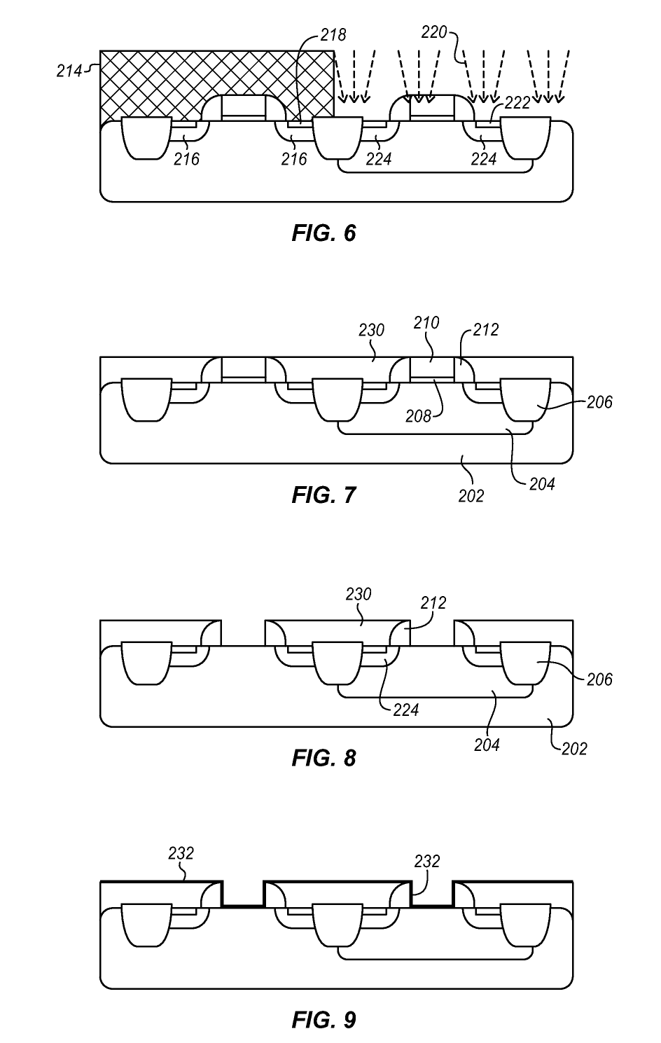

FIG. 6, shows the substrate 202 after forming source and drain areas 216 on both sides of the PMOS gate oxide and spacers by implantation. During this process the NMOS areas are all covered with an implant mask. At the stage shown in FIG. 6, a new implant mask 214 has been formed and patterned to cover the PMOS areas.

An implantation 220 is then applied to the exposed NMOS areas to form the source and drain areas 224 for the NMOS device. As with the PMOS areas these are formed by masking the other areas and then implanting an appropriate dopant. The structure has then been annealed to form conductive S/D contact areas 216 over the S/D areas for PMOS and contact areas 224 over the S/D of NMOS. Salicidation areas 218 and 222 are optionally formed to complete the source and drain implants on top of S/D areas of 216 and 224.

FIG. 7 shows an ILD (Inter-Layer Dielectric) layer 230 deposited over the entire structure. This layer is then polished to expose the top of the polysilicon 210. In FIG. 8, the polysilicon 210 and oxide 208 are removed from the gate areas. These have been used in the formation of the S/D areas and are optimized for the implantation process of FIG. 6 but are not used later. In the illustrated example, the polysilicon gate and regular oxide layers have served to protect the channel areas under the gate during the doping processes, as well as defining the metal gate position for the following process steps. The ILD 230 remains over the rest of the structure. The ILD may be SiO₂ or variations of it with different dopants or nitrides.

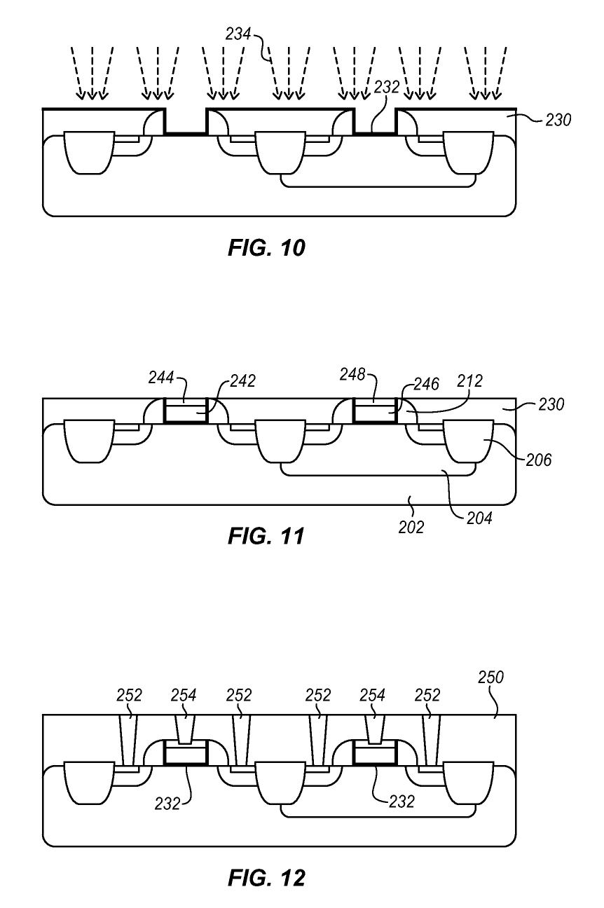

In FIG. 9, a high k metal oxide layer 232 is blanket deposited over the entire structure. This prepares the structure for the large molecule implant 234 of FIG. 10. Areas outside of the antifuse devices are covered with a protective layer such as photo resist so that only the antifuse elements are exposed for the implant 234. In FIG. 10, the device is then implanted 234 with a heavy ion or molecule. In one example SiF₄ is used as the implant molecule. However a variety of other materials may be used instead, such as argon and nitrogen. The channel material may be formed of Si, Ge, II-V or any other semiconductor materials. This implantation modifies the programming voltage for the antifuse circuitry by damaging the underlying structure. The programming voltage is lower than before the implant and allows the programming drivers to be built at lower cost and to be operated with less power.

The implant process provides enough energy to penetrate the gate metal oxide 232, if present, and damage the metal gates. In this case, the gate areas of the eventual antifuse circuits are defined by the high k metal oxide 232 that has been deposited between the spacers. The momentum of the implant particles (mass times velocity) determines the amount of damage that is done. The particles are driven so that they are not able to significantly penetrate the areas protected by the top protective ILD layer 230. As a result, only the gates are damaged. The gates are damaged enough to still operate but to have a lower breakdown voltage.

In the illustrated example, the metal gate oxides 232 are directly exposed to the implant 234. The polysilicon 210 applied earlier has been removed. However, this is not required. The polysilicon or another material may be used to provide an additional control over the effect of the implant process. The temperature, energy, molecule selection and other factors may be used to control the effect of the implant. These control factors may also be combined with an additional layer in the gate (not shown) and the thickness and type of such a gate cover to more precisely control the effect of the implant. The described implant process is effective with high K metal gates to reduce the programming voltage. However, it may also be applied to other types of gates as mentioned above.

The heavy ion implantation may be performed in different ways. A plasma immersion ion implantation system may be used with SiF₄ at 4-6 keV to drive the ions into an electrostatically charged wafer. This may be followed by a short high temperature anneal for a few minutes at a temperature of 900° C. or more.

In FIG. 11, the gates are formed. After the implant process 234, new metal gate materials 242, 246 are applied for both types of transistors. Different metals with different work functions may be used for the n-type and p-type transistors. These may be performed by first masking all but one type of gate, depositing the desired material, then masking all but the other type of gate and depositing the other desired material. In this way different materials may be deposited. In addition, new metal gate contacts 244, 246 are applied over the gate dielectrics. The gate metal layers and the high k metal oxide layer are then polished to remove the excess metals and leaving them only inside the metal gates.

In FIG. 12, an inter-layer dielectric layer 250 is formed over the entire structure and then polished. Electrodes 252 may be formed over the S/D contacts and electrodes 254 may be formed over the gate contacts. These may be formed, for example, by using a dry etch through the ILD, followed by metal deposition of the etched areas, and then a polish to remove the excess metal. The electrodes may be used later to supply a breakdown voltage to program the antifuse circuit. FIG. 12 shows a finished n-type and p-type antifuse transistor suitable for use in the array of FIG. 1. There may be many such antifuse elements to form multiple arrays. The same principles may be applied to make other antifuse devices other than transistors. The devices may be finished with additional layers for isolation, new circuitry devices, connections between devices etc. Interlayer dielectric layers and covers of various kinds may be applied as well depending on the other components to be formed on the die and the intended use of the device. The programming voltage necessary to break down the gate (the breakdown voltage) is determined by the gate oxide breakdown voltage for the particular antifuse element. For a high K metal gate with a metal oxide dielectric, the breakdown voltage is typically higher than for a SiO₂ oxide gate. At the same time, the leakage current is lower for a high K metal gate. When a sufficiently high voltage is applied to the gate, the high electrical field breaks down at least a part of the gate oxide layer over the transistor channel and causes a conductive path to be formed through the oxide between the gate electrode and the underlying channel.

In addition to breaking through the gate material, some of the gate material may be transferred into the channel. This is in part caused by the heat generated by the discharge that breaks through the gate metal. The materials transfer and heat may fuse the metal gate and the silicon substrate together causing the gate of the programmed fuse bits to short to the substrate or channel of the device.

The gate oxide is weakened by the defects caused by the implant process. Implanting foreign materials into the gate oxide induces defects in the oxide. The weakened oxide has a lower breakdown voltage but it still has a low leakage current before breakdown. A SiF₄ implant as described herein may be used to reduce the breakdown voltage by as much as one third. As an example, the breakdown voltage may be 3V without using the implant operation and 2V after the implant operation. Thin metal gate oxide NMOS and PMOS structures show similar results.

The process of FIGS. 2-12 is shown as an example only. The implant may be applied to a variety of different structures made from a variety of different materials. The implant may be done at different times in the process other than that shown. The implant process may be applied to any metal or polysilicon gate fabrication process and to other types of antifuse circuits. By adjusting the oxide layers and adjusting the parameters of the implant process, the programming voltage may be controlled. Different amounts of implant may be used to obtain different programming voltages. For a system with different antifuse circuit structures, the implant process may be used to adjust the different types of antifuse circuits to fuse with the same or a similar programming voltage. Alternatively similar antifuse circuits may be implanted differently so that they have different programming voltages even with the same structure. The fabrication process examples are presented as planar CMOS devices on a silicon substrate. However the implant technique may also be applied to other types of antifuse structures such as FinFET and 3D transistor structures. In some cases, the implant may be driven at an angle to the top of the wafer so that the molecules strike a gate that has a vertical orientation.

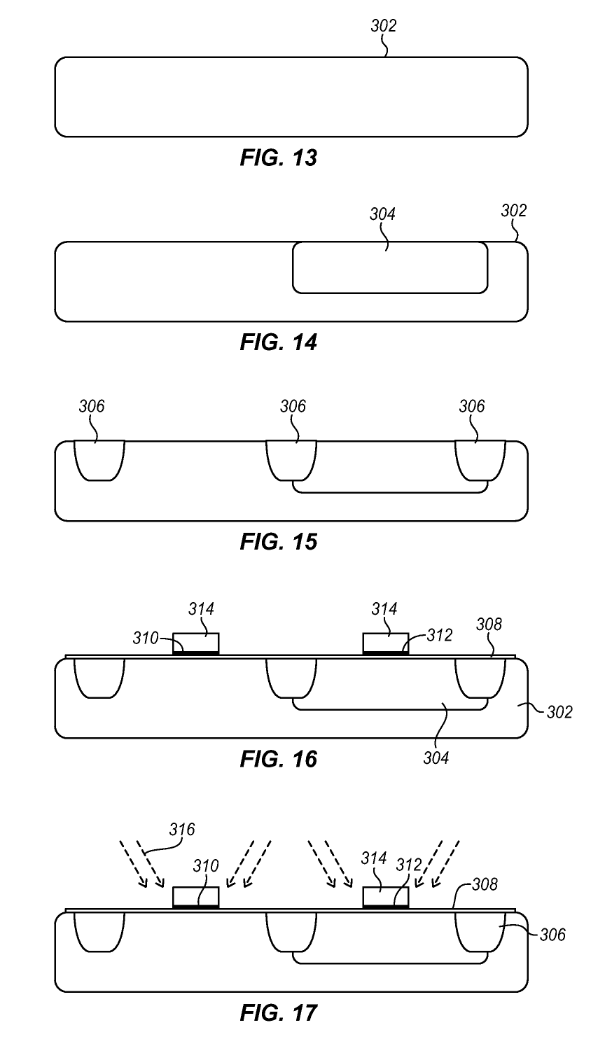

FIGS. 13-19 are cross-sectional side view diagrams of an alternative sequence of processing stages in a second fabrication sequence for production of an antifuse circuit with a lowered programming voltage. In FIGS. 2-12 the gate was formed last, that is after the source and drain areas are formed. In this second fabrication sequence of FIGS. 13-19, the gates are formed first, that is before the source and drain areas are formed.

In FIG. 13, a substrate 302 is used. The substrate may be silicon, or any other suitable material for forming semiconductor circuitry. FIG. 14 shows the substrate 302 of FIG. 13 after an n-well 304 has been formed on one side. Any number of wells may be formed, in this example only one well is formed for an n-well on the right and a p-well for the left side transistor. FIG. 15 shows the addition of shallow trench isolation (STI) areas 306 on either side of both wells. Thus there are three STI areas 306 on each side of both wells and a shared one between the wells.

FIG. 16 shows the substrate 302 with the deposition of an oxide layer 308 over the entire surface of the structure. This may be a regular oxide or a high k metal oxide. Metal gates 310, 312 may be deposited for high k metal gate structures. Two different metals may be used with two different work functions, one for the n-type areas and a different one for the p-type areas, depending on the particular implementation. The metals are then covered in a polysilicon layer 314. For a polysilicon gate with a regular oxide, the polysilicon could be directly deposited on the oxide without the metal layers. The gate structures may be formed by patterning a mask layer and then etching away the poly and the metal layer underneath. This leaves the poly and metal stack, if present, only in the locations of the eventual gates that will be formed on the substrate. This leaves the gate oxide covering the gate areas and the metal oxide (or regular oxide) covering all of the other areas. The gate oxide together with the different work function metals, if present, and the polysilicon define the gate areas. The gate areas are the areas underneath and including the polysilicon 314.

In FIG. 17, the device is then implanted 316 with a heavy ion or molecule, such as SiF₄, Argon and Nitrogen at an angle. This implant process is similar to that described for the first fabrication process with one important difference. This implant process damages primarily the corners of the metal gates 310, 312 to lower the breakdown voltage specifically in those areas. This is due to the angled implant that allows penetration of the heavy ions or molecules through the corners of the polysilicon and the metal layer where it is thin enough to penetrate by the implant ions at an angle. It also leaves impurities in the S/D areas beside the gates and in the channel under the gate. In the illustrated example, the gate oxide in the middle of the metal gates is not directly exposed to the implant 316 because of the additional polysilicon 314. The polysilicon moderates the effect of the implant on the gate oxide and other gate layers. Other layers may also be used to control the effect of the implant. After the implant process, metal gate oxide (or regular gate oxide) materials at corners of 314 are changed by the process and now have the lower breakdown voltage.

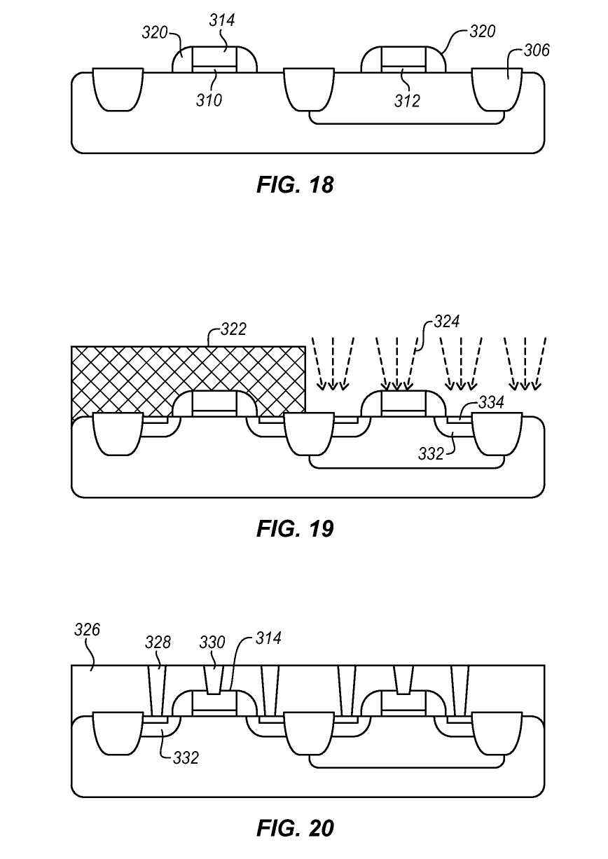

In FIG. 18, the base oxide layer 308 is removed from all of the structure except for under the gates. The base oxide is protected by the metal gates 310, 312 and the polysilicon. Spacers 320, such as silicon nitride spacers, are optionally formed surrounding each gate.

FIG. 19 shows the substrate 302 after depositing source and drain areas 332 for the NMOS device. These are formed by a patterned implant operation 324 with a suitable dopant. A mask layer 322 protects one type of structure while the other one is implanted. The process is repeated for the other devices with a mask over the implanted structures. Metal contact layers 334 are formed by annealing the source and drain areas of both devices to allow for external connections to the devices. Salicidation areas are optionally formed on either side of the well 304.

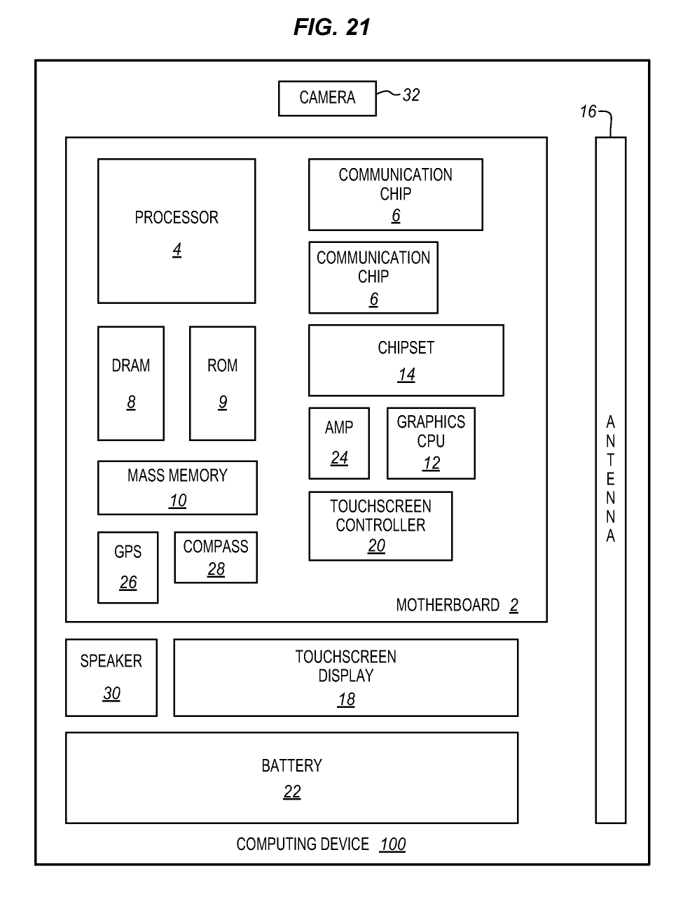

FIG. 20 shows that a protective layer 326 such as a dielectric oxide or ILD is applied over the entire surface of the substrate then polished to a flat surface. Vias may be etched to the gates 314. Electrodes 330 may then be formed over the gate contacts by filing the vias. Additional electrodes are formed over the S/D areas 332. The antifuse devices are finished. However, additional layers may be added to provide additional devices, routing, redistribution and other functions. Additional interlayer dielectric layers and covers may also be applied. These devices may be used for all of the applications and configurations for which the devices of FIG. 12 may be used.

FIG. 21 illustrates a computing device 11 in accordance with one implementation. The computing device 11 houses a board 2. The board 2 may include a number of components, including but not limited to a processor 4 and at least one communication chip 6. The processor 4 is physically and electrically coupled to the board 2. In some implementations the at least one communication chip 6 is also physically and electrically coupled to the board 2. In further implementations, the communication chip 6 is part of the processor 4.

Depending on its applications, computing device 11 may include other components that may or may not be physically and electrically coupled to the board 2. These other components include, but are not limited to, volatile memory (e.g., DRAM) 8, non-volatile memory (e.g., ROM) 9, flash memory (not shown), a graphics processor 12, a digital signal processor (not shown), a crypto processor (not shown), a chipset 14, an antenna 16, a display 18 such as a touchscreen display, a touchscreen controller 20, a battery 22, an audio codec (not shown), a video codec (not shown), a power amplifier 24, a global positioning system (GPS) device 26, a compass 28, an accelerometer (not shown), a gyroscope (not shown), a speaker 30, a camera 32, and a mass storage device (such as hard disk drive) 10, compact disk (CD) (not shown), digital versatile disk (DVD) (not shown), and so forth). These components may be connected to the system board 2, mounted to the system board, or combined with any of the other components. The communication chip 6 enables wireless and/or wired communications for the transfer of data to and from the computing device 11. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 6 may implement any of a number of wireless or wired standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, Ethernet derivatives thereof, as well as any other wireless and wired protocols that are designated as 3G, 4G, 5G, and beyond. The computing device 11 may include a plurality of communication chips 6. For instance, a first communication chip 6 may be dedicated to shorter range wireless communications such as Wi-Fi and Bluetooth and a second communication chip 6 may be dedicated to longer range wireless communications such as GPS, EDGE, GPRS, CDMA, WiMAX, LTE, Ev-DO, and others.

In some implementations, the integrated circuit unit of the processor, memory devices, communication devices, or other components includes or is packaged with programmed antifuse circuits to contain operational parameters, configuration parameters, identification information, encryption keys or other information as described herein. The term “processor” may refer to any device or portion of a device that processes electronic data from registers and/or memory to transform that electronic data into other electronic data that may be stored in registers and/or memory.

In various implementations, the computing device 11 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 11 may be any other electronic device that processes data including a wearable device.

Embodiments may be implemented as a part of one or more memory chips, controllers, CPUs (Central Processing Unit), microchips or integrated circuits interconnected using a motherboard, an application specific integrated circuit (ASIC), and/or a field programmable gate array (FPGA).

References to “one embodiment”, “an embodiment”, “example embodiment”, “various embodiments”, etc., indicate that the embodiment(s) so described may include particular features, structures, or characteristics, but not every embodiment necessarily includes the particular features, structures, or characteristics. Further, some embodiments may have some, all, or none of the features described for other embodiments.

In the following description and claims, the term “coupled” along with its derivatives, may be used. “Coupled” is used to indicate that two or more elements co-operate or interact with each other, but they may or may not have intervening physical or electrical components between them.

As used in the claims, unless otherwise specified, the use of the ordinal adjectives “first”, “second”, “third”, etc., to describe a common element, merely indicate that different instances of like elements are being referred to, and are not intended to imply that the elements so described must be in a given sequence, either temporally, spatially, in ranking, or in any other manner. The drawings and the forgoing description give examples of embodiments. Those skilled in the art will appreciate that one or more of the described elements may well be combined into a single functional element. Alternatively, certain elements may be split into multiple functional elements. Elements from one embodiment may be added to another embodiment. For example, orders of processes described herein may be changed and are not limited to the manner described herein. Moreover, the actions of any flow diagram need not be implemented in the order shown; nor do all of the acts necessarily need to be performed. Also, those acts that are not dependent on other acts may be performed in parallel with the other acts. The scope of embodiments is by no means limited by these specific examples. Numerous variations, whether explicitly given in the specification or not, such as differences in structure, dimension, and use of material, are possible. The scope of embodiments is at least as broad as given by the following claims. The following examples pertain to further embodiments. The various features of the different embodiments may be variously combined with some features included and others excluded to suit a variety of different applications. Some embodiments pertain to method that includes forming an antifuse circuit on a substrate, including forming a gate area of the antifuse circuit, implanting a molecule into the gate area to damage the structure of the gate area, forming electrodes over the gate area to connect the antifuse circuit to other components. Further embodiments include forming a gate dielectric and wherein implanting comprises implanting into the gate dielectric to damage the gate dielectric and a channel under the gate dielectric in the gate area.

In some embodiments forming a gate dielectric comprises forming a high K metal oxide gate dielectric.

In some embodiments the damaged gate dielectric comprises an antifuse element for the antifuse circuit.

Further embodiments include depositing a second gate dielectric and a polysilicon gate material over the gate area, doping source and drain areas, and removing the gate dielectric and polysilicon gate material after doping and before implanting.

Further embodiments include depositing a second gate dielectric over the gate after removing the first gate dielectric and before implanting.

Further embodiments include forming a gate dielectric over the gate area and forming a gate material over the gate area before implanting and wherein implanting further damages the structure of the gate dielectric.

In some embodiments implanting comprises implanting a SiF4 molecules into the gate area.

In some embodiments implanting comprises a plasma immersion ion implantation.

Further embodiments include applying a gate metal oxide over the gate area before implanting and then forming gate metal layers over the metal oxide after implanting.

Further embodiments include forming a polysilicon layer over the gate areas, implanting source and drain areas beside the gate areas and removing the polysilicon layer over the gate areas before implanting.

Some embodiments pertain to an antifuse circuit that includes a source and a drain over a well, a channel between the source and the drain, the channel including an implanted molecule impurity, and a gate over the channel, the gate being damaged by the impurity molecule, so that the gate has a reduced breakdown voltage due to the molecule.

In some embodiments the molecule is SiF4.

In some embodiments the gate is a formed of a metal and a high K metal oxide gate dielectric.

Further embodiments include a gate dielectric over the channel.

Further embodiments include a damaged gate metal oxide between the channel and the gate.

Further embodiments include a work function metal between the damaged gate metal oxide and the gate, the work function metal not being damaged by the impurity molecule.

Some embodiments pertain to a computing system that includes a processor, a mass memory coupled to the processor, and a programmable read only memory coupled to the processor having a plurality of antifuse transistors, each antifuse transistor comprising a source and a drain over a well, a channel between the source and the drain, the channel including an implanted molecule impurity and a gate dielectric over the channel to form a gate, the gate dielectric being damaged by the impurity molecule, so that the gate has a reduced breakdown voltage due to the molecule.

In some embodiments the programmable read only memory comprises a high voltage fuse signal driver to program each respective antifuse transistor.

Further embodiments include a gate metal over the channel and the gate dielectric.

1-20. (canceled)

21. A method comprising:
forming an antifuse circuit on a substrate, including forming a gate area of the antifuse circuit;
implanting a molecule into the gate area to damage the structure of the gate area;
forming electrodes over the gate area to connect the antifuse circuit to other components.

22. The method of claim 21, further comprising forming a gate dielectric and wherein implanting comprises implanting into the gate dielectric to damage the gate dielectric and a channel under the gate dielectric in the gate area.

23. The method of claim 22, wherein forming a gate dielectric comprises forming a high K metal oxide gate dielectric

24. The method of claim 22, wherein the damaged gate dielectric comprises an antifuse element for the antifuse circuit.

25. The method of claim 21, further comprising:
depositing a second gate dielectric and a polysilicon gate material over the gate area;
doping source and drain areas; and
removing the gate dielectric and polysilicon gate material after doping and before implanting.

26. The method of claim 25, further comprising depositing a second gate dielectric over the gate after removing the first gate dielectric and before implanting.

27. The method of claim 21, further comprising:
forming a gate dielectric over the gate area; and
forming a gate material over the gate area before implanting, and
wherein implanting further damages the structure of the gate dielectric.

28. The method of claim 21, wherein implanting comprises implanting a SiF4 molecules into the gate area.

29. The method of claim 21, wherein implanting comprises a plasma immersion ion implantation.

30. The method of claim 21, further comprising:
applying a gate metal oxide over the gate area before implanting; and
then forming gate metal layers over the metal oxide after implanting.

31. The method of claim 30, further comprising:
forming a polysilicon layer over the gate areas;
implanting source and drain areas beside the gate areas; and
removing the polysilicon layer over the gate areas before implanting.

32. An antifuse circuit comprising:
a source and a drain over a well;
a channel between the source and the drain, the channel including an implanted molecule impurity; and
a gate over the channel, the gate being damaged by the impurity molecule, so that the gate has a reduced breakdown voltage due to the molecule.

33. The circuit of claim 32, wherein the molecule is SiF4.

34. The circuit of claim 32, wherein the gate is a formed of a metal and a high K metal oxide gate dielectric.

35. The circuit of claim 32, further comprising a gate dielectric over the channel.

36. The circuit of claim 35, further comprising a damaged gate metal oxide between the channel and the gate.

37. The circuit of claim 35, further comprising a work function metal between the damaged gate metal oxide and the gate, the work function metal not being damaged by the impurity molecule.

38. A computing system comprising:
a processor;
a mass memory coupled to the processor; and
a programmable read only memory coupled to the processor having a plurality of antifuse transistors, each antifuse transistor comprising:
a source and a drain over a well;
a channel between the source and the drain, the channel including an implanted molecule impurity; and
a gate dielectric over the channel to form a gate, the gate dielectric being damaged by the impurity molecule, so that the gate has a reduced breakdown voltage due to the molecule.

39. The computing system of claim 38, wherein the programmable read only memory comprises a high voltage fuse signal driver to program each respective antifuse transistor.

40. The computing system of claim 38, further comprising a gate metal over the channel and the gate dielectric.
